(19) United States
(12) Patent Application Publication
(10) Pub. No.: US 2026/0269553 A1
(43) Pub. Date: Sep. 10, 2026

(54) LASER CHAMBER APPARATUS, LASER APPARATUS, AND ELECTRONIC DEVICE MANUFACTURING METHOD

(71) Applicant: Gigaphoton Inc., Tochigi (JP)

(72) Inventors: Rei TAKENAKA, Tochigi (JP); Youichi YAMANOUCHI, Tochigi (JP)

(73) Assignee: Gigaphoton Inc., Tochigi (JP)

(21) Appl. No.: 19/531,713

(22) Filed: Feb. 6, 2026

(30) Foreign Application Priority Data
Mar. 7, 2025 (JP) 2025-036526

(51) Int. Cl. H01S 3/038; G03F 7/00

(52) U.S. Cl. CPC H01S 3/038; G03F 7/70025; H01S 3/0381; H01S 3/0384

(57) ABSTRACT

A laser chamber apparatus includes a chamber body, a first discharge electrode disposed in an internal space of the chamber body and having a longitudinal direction aligned with an optical axis of the laser light, a second discharge electrode so disposed in the internal space that the second discharge electrode faces the first discharge electrode and has a longitudinal direction aligned with the optical axis of the laser light, a return member electrically connecting the second discharge electrode to the chamber body over a length from one end to another end of the second discharge electrode in the longitudinal direction, and a support member supporting the second discharge electrode with respect to the chamber body. Either of (i) the support member and the chamber body or (ii) the second discharge electrode and the support member are connected to each other via multiple insulators.

### CROSS-REFERENCE TO RELATED APPLICATIONS

The present application claims the benefit of Japanese Patent Application No. 2025-036526, filed on Mar. 7, 2025, the entire contents of which are hereby incorporated by reference.

### BACKGROUND

### 1. Technical Field

The present disclosure relates to a laser chamber apparatus, a laser apparatus, and an electronic device manufacturing method.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from KrF and ArF excimer laser apparatuses performing spontaneous laser oscillation has a wide spectral linewidth ranging from 350 to 400 pm. A projection lens made of a material that transmits ultraviolet light, such as the KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon or grating) is provided in some cases in a laser resonator of the gas laser apparatus to narrow the spectral linewidth. A gas laser apparatus providing a narrowed spectral linewidth is hereinafter referred to as a narrowed-line gas laser apparatus.

### CITATION LIST

### Patent Literature

[PTL 1] U.S. Pat. No. 9,331,450

[PTL 2] U.S. Pat. No. 6,414,979

### SUMMARY

A laser chamber apparatus according to an aspect of the present disclosure may be a laser chamber apparatus configured to output laser light. The laser chamber apparatus may include a chamber body, a first discharge electrode, a second discharge electrode, a return member, and a support member. The first discharge electrode may be disposed in an internal space of the chamber body and have a longitudinal direction aligned with an optical axis of the laser light. The second discharge electrode may be so disposed in the internal space that the second discharge electrode faces the first discharge electrode and have a longitudinal direction aligned with the optical axis of the laser light. The return member may electrically connect the second discharge electrode to the chamber body over a length from one end to another end of the second discharge electrode in the longitudinal direction. The support member may support the second discharge electrode with respect to the chamber body. Either of (i) the support member and the chamber body or (ii) the second discharge electrode and the support member may be connected to each other via multiple insulators.

A laser apparatus according to another aspect of the present disclosure may be a laser apparatus including a laser chamber apparatus configured to output laser light. The laser chamber apparatus may include a chamber body, a first discharge electrode, a second discharge electrode, a return member, and a support member. The first discharge electrode may be disposed in an internal space of the chamber body and have a longitudinal direction aligned with an optical axis of the laser light. The second discharge electrode may be so disposed in the internal space that the second discharge electrode faces the first discharge electrode and have a longitudinal direction aligned with the optical axis of the laser light. The return member may electrically connect the second discharge electrode to the chamber body over a length from one end to another end of the second discharge electrode in the longitudinal direction. The support member may support the second discharge electrode with respect to the chamber body. Either of (i) the support member and the chamber body or (ii) the second discharge electrode and the support member may be connected to each other via multiple insulators.

An electronic device manufacturing method according to further another aspect of the present disclosure may include: generating laser light by using a laser apparatus; outputting the laser light to an exposure apparatus; and exposing a photosensitive substrate to the laser light in the exposure apparatus to manufacture electronic devices. The laser apparatus may include a laser chamber apparatus including a chamber body, a first discharge electrode, a second discharge electrode, a return member, and a support member. The first discharge electrode may be disposed in an internal space of the chamber body and have a longitudinal direction aligned with an optical axis of the laser light. The second discharge electrode may be so disposed in the internal space that the second discharge electrode faces the first discharge electrode and have a longitudinal direction aligned with the optical axis of the laser light. The return member may electrically connect the second discharge electrode to the chamber body over a length from one end to anther end of the second discharge electrode in the longitudinal direction. The support member may support the second discharge electrode with respect to the chamber body. Either of (i) the support member and the chamber body or (ii) the second discharge electrode and the support member may be connected to each other via multiple insulators.

### BRIEF DESCRIPTION OF DRAWINGS

Some embodiments of the present disclosure will be described below only by way of example with reference to the accompanying drawings.

FIG. 1 schematically shows the configuration of a laser apparatus according to Comparative Example.

FIG. 2 schematically shows the configuration of a discharger of the laser apparatus.

FIG. 3 is a perspective view of a return plate.

FIG. 4 schematically shows an example of a structure that fixes an anode support and an anode to each other.

FIG. 5 shows measurement points where currents flowing through the return plate in a chamber apparatus are measured.

FIG. 6 is a graph showing current values of the currents flowing through returns at measurement points in FIG. 5.

FIG. 7 shows the configuration of the chamber apparatus using an anode support made of an insulating material.

FIG. 8 shows the structure of a chamber apparatus according to a first embodiment.

FIG. 9 shows an example of the cross-sectional view taken along the line 9-9 in FIG. 8.

FIG. 10 shows another example of the cross-sectional view taken along the line 9-9 in FIG. 8.

FIG. 11 shows another example of the cross-sectional view taken along the line 9-9 in FIG. 8.

FIG. 12 shows another example of the cross-sectional view taken along the line 9-9 in FIG. 8.

FIG. 13 shows the structure of a chamber apparatus according to a fourth embodiment.

FIG. 14 schematically shows the configuration of an exposure apparatus.

### DETAILED DESCRIPTION

### Contents

1. Overview of laser apparatus according to Comparative Example
1.1 Configuration
1.2 Operation
1.3 Problems
2. First embodiment
2.1 Configuration
2.2 Operation
2.3 Effects and advantages
2.4 Variation of first embodiment
3. Second embodiment
3.1 Configuration
3.2 Operation
3.3 Effects and advantages
4. Third embodiment
4.1 Configuration
4.2 Operation
4.3 Effects and advantages
5. Fourth embodiment
5.1 Configuration
5.2 Operation
5.3 Effects and advantages
6. Electronic device manufacturing method
7. Others

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same elements have the same reference characters, and no redundant description of the same elements will be made.

1. Overview of laser apparatus according to Comparative Example

### 1.1 Configuration

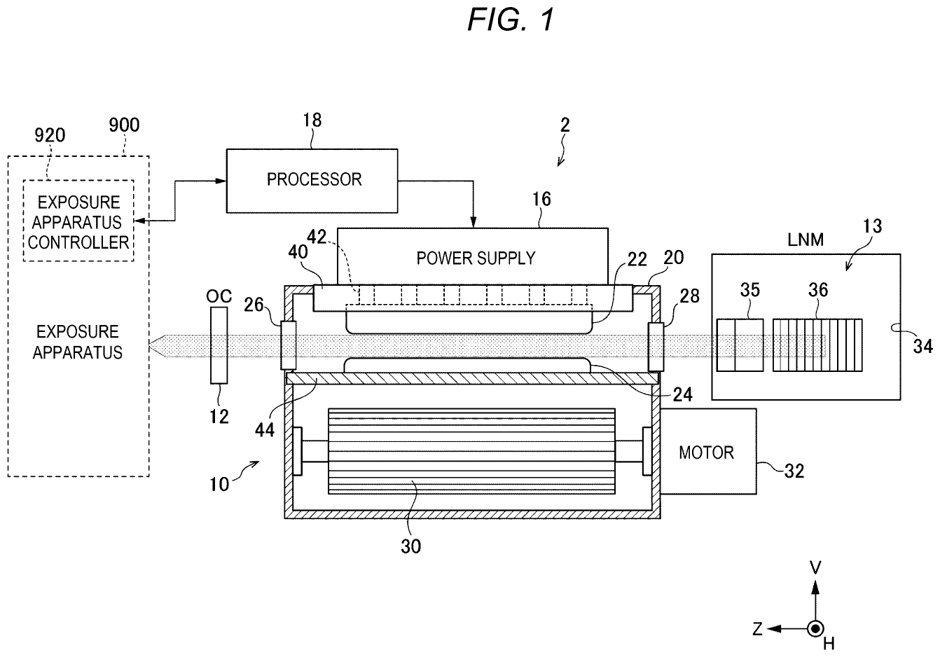

FIG. 1 schematically shows the configuration of a laser apparatus 2 according to Comparative Example. Comparative Example of the present disclosure is an aspect that the applicant is aware of as known only by the applicant, and is not a publicly known example that the applicant is self-aware of. In FIG. 1, the traveling direction of laser light output from the laser apparatus 2 is defined as a Z-axis direction. An H-axis direction and a V-axis direction are directions perpendicular to the Z-axis direction and perpendicular to each other. The direction perpendicular to the plane of view of FIG. 1 is defined as the H-axis direction. The following drawings also use the same Z-axis direction, H-axis direction, and V-axis direction defined in FIG. 1.

The laser apparatus 2 is an excimer laser apparatus including a chamber apparatus 10, an output coupler (OC) 12, a line narrowing module (LNM) 13, a power supply 16, and a processor 18. The chamber apparatus 10 includes a chamber body 20, a cathode 22, an anode 24, windows 26 and 28, a crossflow fan 30, and a motor 32.

The LNM 13 includes an enclosure 34, multiple prisms 35, and a grating 36. The multiple prisms 35 are, for example, three prisms, and are disposed to function as a beam expander that expands incident light in the H-axis direction. The grating 36 is disposed in the Littrow arrangement, which causes the angle of incidence of the light incident on the grating 36 to be equal to the angle of diffraction of the light diffracted by the grating 36. The enclosure 34 positions and houses the multiple prisms 35 and the grating 36.

The OC 12 and the grating 36 of the LNM 13 constitute an optical resonator. The chamber apparatus 10 is disposed in the optical path of the optical resonator.

The OC 12 and the LNM 13 are positioned and held by a cavity plate that is not shown but is provided in a laser frame that is not shown. The cavity plate may have a through hole through which the laser light passes.

The cathode 22 and the anode 24, which are a pair of discharge electrodes, each have a substantially rectangular parallelepiped shape having curved surfaces at opposite ends in the longitudinal direction. The cathode 22 and the anode 24 face each other in the V-axis direction, which is perpendicular to the H-axis direction, in the internal space of the chamber body 20, and the two electrodes are so disposed that the longitudinal directions thereof coincide with the optical path direction of the optical resonator.

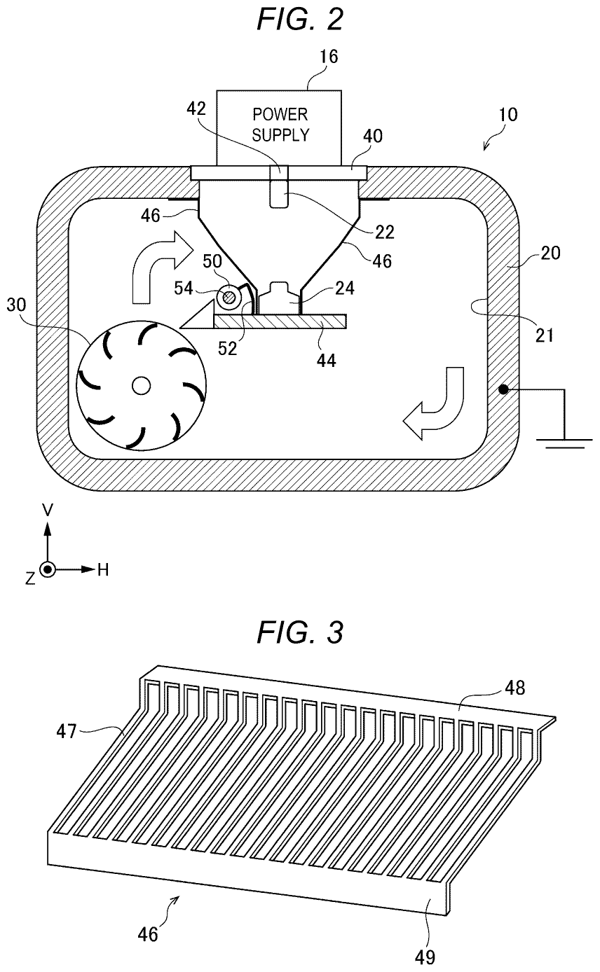

The cathode 22 is connected to the power supply 16 via feedthroughs 42 passing through an insulating plate 40 positioned in the chamber body 20. The anode 24 is electrically connected to the chamber body 20 via return plates (see FIG. 2), which will be described later, and is positioned in the chamber body 20 by an anode support 44, which holds the anode 24.

The chamber body 20 is a container filled with a laser gas. The laser gas is, for example, a mixture gas containing an Ar gas or a Kr gas as a rare gas, a F₂ gas as a halogen gas, and a Ne gas or a He gas as a buffer gas.

The crossflow fan 30 is connected to the motor 32, and rotating the shaft of the motor 32 causes the laser gas to circulate in the chamber body 20.

The power supply 16 may, for example, be a pulse power module including a charging capacitor and a switch. The power supply 16 generates discharge between the cathode 22 and the anode 24 in response to an instruction from the processor 18.

The laser light produced by discharge excitation between the discharge electrodes and amplified by the optical resonator passes through the windows 26 and 28. The discharge direction in this process is the V-axis direction. The windows 26 and 28, which each have a surface on which the laser light is incident, are each so disposed that the pulse laser light is incident on the surface at an angle close to Brewster's angle with respect to the VZ plane.

The processor 18 is connected, for example, to an exposure apparatus controller 920 of an exposure apparatus 900. The processor 18 functions as an apparatus that controls the laser apparatus 2. The processor 18 is a processing apparatus including a storage apparatus that stores a control program and a CPU (central processing unit) that executes the control program. The processor 18 is particularly configured or programmed to carry out various processes described in the present disclosure. The storage apparatus is a tangible, non-transitory computer readable medium, including, for example, a memory that is a primary storage and a storage that is an auxiliary storage apparatus. The computer readable medium may, for example, be a semiconductor memory, a hard disk drive (HDD), or a solid state drive (SSD), or a combination of a plurality of the components described above.

FIG. 2 schematically shows the configuration of a discharger of the laser apparatus 2. FIG. 2 is a cross-sectional view of the chamber apparatus 10 shown in FIG. 1 viewed in the Z-axis direction.

In the direction in which the crossflow fan 30 causes the circulating flow to flow, the side upstream of the space across which the cathode 22 and the anode 24 face each other is simply referred to as “upstream”, and the side downstream of the space across which the cathode 22 and the anode 24 face each other is simply referred to as “downstream”.

Return plates 46, which are electrically connected to the chamber body 20, are disposed upstream and downstream of the anode 24. The return plates 46 are each shaped as a ladder in which multiple linear portions are so arranged in parallel that the return plate 46 does not block the circulating flow circulated by the crossflow fan 30.

FIG. 3 is a perspective view of one of the return plates 46. The return plate 46 has a structure in which multiple linear portions 47 are arranged at substantially equal intervals, one end of each of the linear portions 47 being connected to a first fixing portion 48, and the other end being connected to a second fixing portion 49. The return plate 46 is formed, for example, by punching a single metal plate.

The multiple linear portions 47 are arranged in parallel over the length substantially equal to the longitudinal length of the anode 24, and the return plate 46 is electrically connected to the chamber body 20 over the range from one longitudinal end to the other longitudinal end of the anode 24. Note that the longitudinal direction of the anode 24 is the Z-axis direction. The multiple linear portions 47, which constitute the ladder, are each referred to as a return.

A pre-ionization outer electrode 52 and a pre-ionization inner electrode 54 are disposed upstream of the anode 24 with a dielectric pipe 50 interposed between the two pre-ionization electrodes, as shown in FIG. 2. The pre-ionization inner electrode 54 is disposed in the dielectric pipe 50. The anode 24, the dielectric pipe 50, the pre-ionization outer electrode 52, and the pre-ionization inner electrode 54 are fixed onto the anode support 44, and the anode support 44 is positioned and connected to a chamber inner wall 21. The chamber inner wall 21 is the inner wall of the chamber body 20.

The pre-ionization inner electrode 54 is connected to the power supply 16 via wiring that is not shown. The pre-ionization outer electrode 52 is connected to the anode support 44. The longitudinal opposite ends of the anode support 44 are positioned and fixed to the chamber inner wall 21.

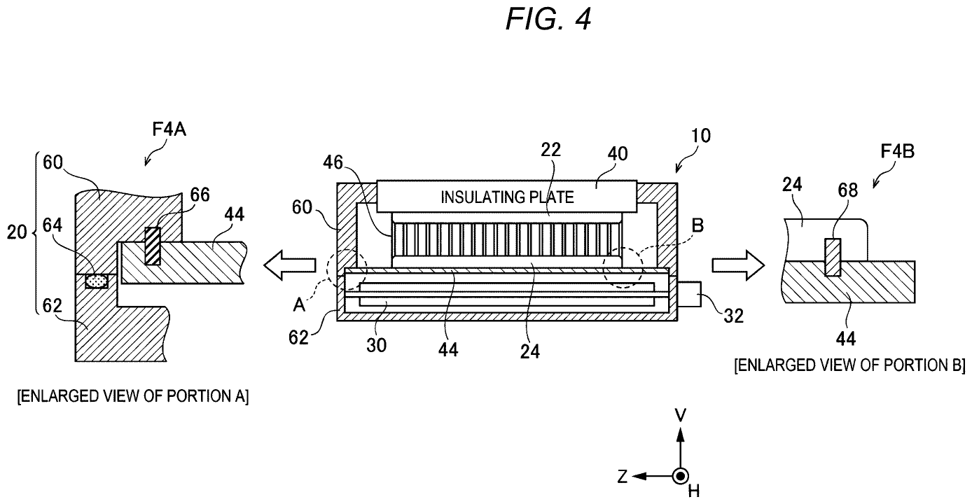

FIG. 4 schematically shows an example of a structure that fixes the anode support 44 and the anode 24 to each other. A partially enlarged view F4A shown in the left part of FIG. 4 is an enlarged cross-sectional view of a portion of the chamber apparatus 10 that is the portion surrounded by a dashed circle A in FIG. 4, and shows a structure that fixes the anode support 44 to the chamber body 20. The chamber body 20 is a hollow structure that is an assembly of an upper case 60 and a lower case 62 with an O-ring 64 interposed therebetween. The cathode 22 is positioned in the upper case 60 via the insulating plate 40, the anode 24 is positioned in the upper case 60 via the anode support 44, and the two electrodes are fixed with bolts or the like. In this process, the anode support 44 is made of metal that is easy to machine, such as aluminum, and is positioned by positioning pins 66. Not only the left end portion of the anode support 44 in FIG. 4, but also the right end portion of the anode support 44 has the same structure as in the partially enlarged view F4A.

A partially enlarged view F4B shown in the right part of FIG. 4 is an enlarged cross-sectional view of a portion of the chamber apparatus 10 that is the portion surrounded by a dashed circle B in FIG. 4, and shows a structure that fixes the anode 24 to the anode support 44. The anode 24 and the anode support 44 are positioned by positioning pins 68 and fixed to each other with bolts or the like, as shown in the partially enlarged view F4B. The anode support 44 thus positions the anode 24 with respect to the cathode 22 via the chamber body 20, and therefore has an important function in ensuring a stable electric field distribution and insulation performance.

### 1.2 Operation

When the laser apparatus 2 is activated, the laser gas in the chamber apparatus 10 is caused to circulate by the crossflow fan 30. When the processor 18 is instructed by the exposure apparatus controller 920 to output the laser light, the processor 18 applies a voltage to the pre-ionization inner electrode 54 in the chamber apparatus 10, and then immediately applies a voltage to the cathode 22 and the anode 24. The resultant corona discharge generated at the surface of the dielectric pipe 50 causes electrons to diffuse between the cathode 22 and the anode 24, so that glow discharge is generated between the cathode 22 and the anode 24.

The discharge excites the laser gas to generate light, which passes through the window 28 and enters the LNM 13, where the light is expanded by the prisms 35 and incident on the grating 36. The light diffracted by the grating 36 travels back along the optical path axis along which the dispersed light is incident on the grating 36, enters the chamber apparatus 10 again, and passes through the discharge region, where the light is amplified.

The light having passed through the window 26 is incident on the OC 12, and part of the light passes through the OC 12. The other part of the light is reflected off the OC 12, passes through the window 26 again, and passes through the discharging region, where the light is amplified. The process described above is repeated for laser oscillation. The laser light travels in the Z-axis direction and exits out of the chamber apparatus 10.

### 1.3 Problems

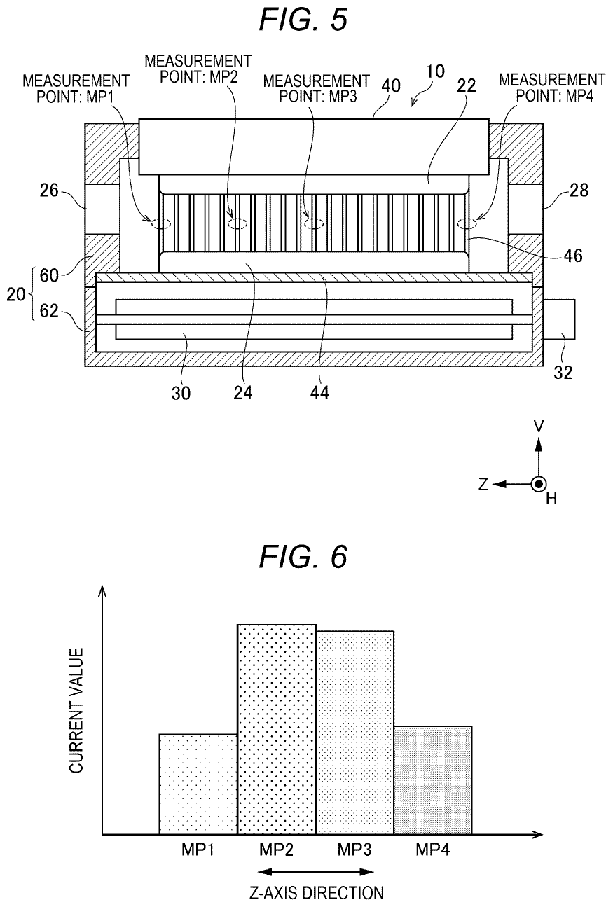

A factor that determines the service life of the chamber apparatus 10 of the laser apparatus 2 is consumption of the cathode 22. The cathode 22 may be consumed unevenly in the Z-axis direction. To figure out the cause of the event described above, examination of currents flowing through returns of each of the return plates 46 at respective positions in the Z-axis direction as shown in FIG. 5 shows that the currents flowing through the returns have a non-uniform distribution in the Z-axis direction.

FIG. 5 shows measurement points where the currents flowing through each of the return plates 46 in the chamber apparatus 10 are measured. FIG. 6 is a graph showing current values of the currents flowing through the returns at measurement points MP1 to MP4 in FIG. 5. In FIG. 6, the horizontal axis represents positions in the Z-axis direction, and the vertical axis represents current values of the current flowing through a return and expressed in a relative value. The measurement point MP1 corresponds to the left-end return of the return plate 46. The measurement point MP2 corresponds to the return located at a position separate from the left end of the return plate 46 by approximately a quarter of the electrode length of the anode 24. The measurement point MP3 corresponds to the return located at a position separate from the left end of the return plate 46 by approximately half of the electrode length of the anode 24 (substantially at center position). The measurement point MP4 corresponds to the right-end return of the return plate 46.

When the current flowing through a return is non-uniform in the Z-axis direction, it is conceivable that the discharge becomes non-uniform in the Z-axis direction, which leads to non-uniform consumption of the discharge electrodes, and deterioration and destabilization of laser performance.

Summation of the currents flowing through all the returns based on the measurement results shown in FIG. 6 shows that the current value of the summed current flowing through the returns is less than even half the current value of the current flowing from the cathode 22 to the anode 24. It can thus be inferred that at least half the original current flows through the anode support 44.

That is, it is considered that a substantial amount of the current that propagates and leaks through the anode support 44 is one cause of the non-uniformity of the currents flowing through the returns, and contributes to the non-uniform consumption of the cathode 22.

Therefore, as a structure that suppresses the current flowing through the anode support 44 without impairing the function of the anode support 44, it is conceivable to form the anode support 44 with an insulating material.

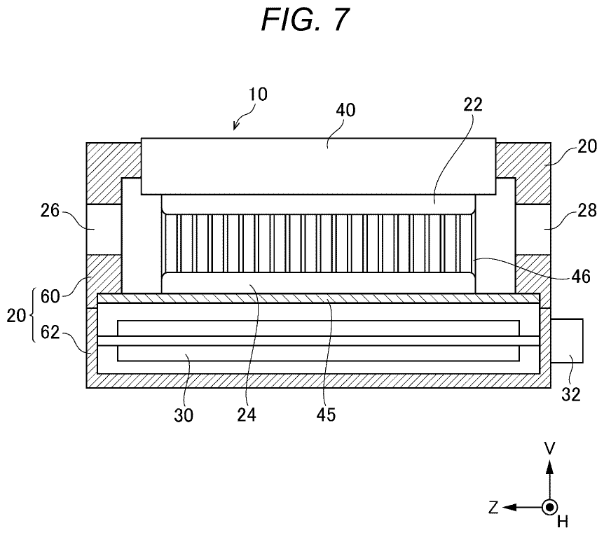

FIG. 7 shows the configuration of the chamber apparatus 10 using an anode support 45 made of an insulating material in place of the anode support 44 made of metal. The other configurations may be the same as those in the chamber apparatus 10 described with reference to FIGS. 1 to 5. The configuration shown in FIG. 7 prevents the discharge current from flowing through the anode support 45, so that the currents flow through the returns as designed.

In the configuration in which the anode support 45 is made of an insulating material, however, the dimension of the anode support 45 may increase, and the shape thereof may be complicated. When the anode support 45 is made of a material having low reactivity with the laser gas, such as a ceramic material, there is a concern that an elongated, complicated shape of the anode support 45 may increase the cost due to deterioration in yield.

Furthermore, since a ceramic material or any other similar material has a thermal expansion coefficient greatly different from those of the metal members, such as the other electrode (anode 24) and the chamber body 20, the two types of materials thermally expand differently when heated during the discharge.

In the configuration shown in FIG. 7, the anode support 45 made of an insulating material needs to be positioned and fixed to the anode 24 made of metal and a chamber component, and may therefore be damaged by stress induced in the thermal expansion.

There has therefore been a demand for a configuration that can be produced at a satisfactory yield and at a low cost while suppressing the leakage of the current through the anode support 44, and can prevent the damage due to the thermal expansion.

### 2. First embodiment

### 2.1 Configuration

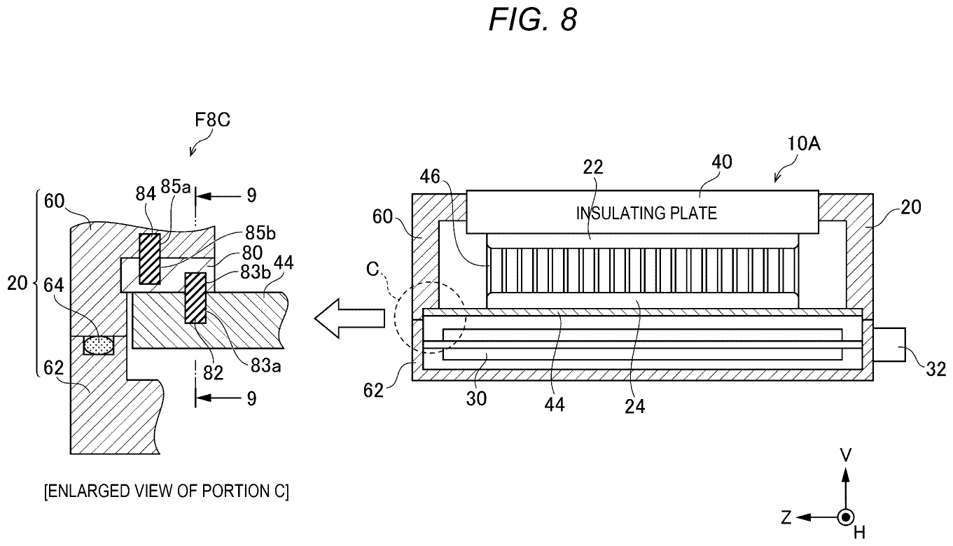

FIG. 8 shows the structure of a chamber apparatus 10A according to a first embodiment. The chamber apparatus 10A is an example of the “laser chamber apparatus” in the present disclosure. A partially enlarged view F8C shown in the left part of FIG. 8 is an enlarged cross-sectional view of a portion of the chamber apparatus 10A that is the portion surrounded by a dashed circle C in FIG. 8, and shows a structure that fixes the anode support 44 to the chamber body 20. Differences in configuration between FIGS. 8 and 4 will be described.

In the chamber apparatus 10A according to the first embodiment, insulators 80 are disposed at opposite ends of the anode support 44 in the Z-axis direction, and the anode support 44 is fixed to the upper case 60 via the insulators 80, so that the anode support 44 and the upper case 60 are insulated from each other. The Z-axis direction is an example of the direction of the “optical axis of the laser light” in the present disclosure.

Positioning pins 82 and 84 are disposed between the anode support 44 and each of the insulators 80 and between the upper case 60 and each of the insulators 80, respectively, and the anode support 44 is positioned with respect to the upper case 60 by the positioning pins 82 and 84.

One of the positioning pins 82 may be disposed at one of opposite end portions of the anode support 44, and the other may not be disposed at the other end portion. One of the positioning pins 84 may be disposed at one of the opposite end portions of the anode support 44 that is closer to a side of the upper case 60 where the positioning pin 82 is disposed than the other is, and the other may not be disposed at the other end portion.

The anode support 44 has holes 83a, into which the positioning pins 82 fit, and the insulators 80 have holes 83b, into which the positioning pins 82 fit. The upper case 60 has holes 85a, into which the positioning pins 84 fit, and the insulators 80 have holes 85b, into which the positioning pins 84 fit. The positioning pins 82 may be fixed to the insulators 80, or may be fixed to the anode support 44. The positioning pins 84 may be fixed to the insulators 80, or may be fixed to the upper case 60. At least one of the positioning pins 82 and 84 may be integrated with the insulators 80. At least one of the positioning pins 82 and 84 and the holes 83b and 85b is an example of the “positioning mechanism” in the present disclosure. Some or all of the holes 83b and 85b are an example of the “positioning hole” in the present disclosure. The positional relationship between the anode support 44 and the upper case 60 is an example of the “positional relationship” in the present disclosure.

The anode support 44 may be made of metal, for example, Ni-plated aluminum or SUS (stainless steel). The insulators 80 may be made of a ceramic material, for example, alumina ceramic. The anode support 44 is an example of the “support member” in the present disclosure. The return plates 46 are an example of the “return member” in the present disclosure. The cathode 22 is an example of the “first discharge electrode” in the present disclosure, and the anode 24 is an example of the “second discharge electrode” in the present disclosure.

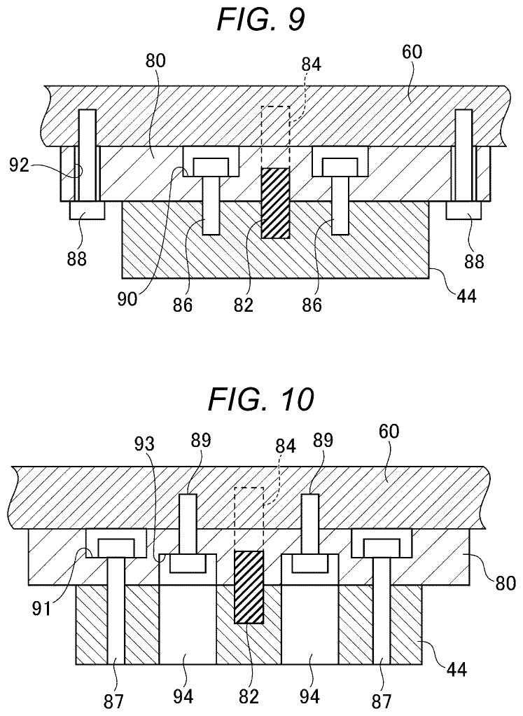

FIG. 9 shows an example of the cross-sectional view taken along the line 9-9 in FIG. 8. A structure that fixes the anode support 44 to the upper case 60 may, for example, be a structure that fixes the anode support 44 and the insulators 80 fixed to each other with fixing bolts 86 to the upper case 60 with fixing bolts 88, as shown in FIG. 9.

In this case, the insulators 80 each have through holes 90, through which the fixing bolts 86 pass, and through holes 92, through which the fixing bolts 88 pass. The through holes 90 are counterbores that prevent the heads of the fixing bolts 86 from being exposed through the insulators 80. The anode support 44 has female threaded holes into which the fixing bolts 86 are screwed. The upper case 60 has female threaded holes into which the fixing bolts 88 are screwed. The fixing bolts 86 are an example of the “bolt” in the present disclosure.

The insulator 80 shown in FIG. 9 is fixed to the anode support 44 and then fixed to the upper case 60.

The other configurations of the chamber apparatus 10A according to the first embodiment are the same as those of the chamber apparatus 10 according to Comparative Example.

### 2.2 Operation

The configuration in which the anode support 44 and the upper case 60 of the chamber apparatus 10A according to the first embodiment are insulated from each other by the insulators 80 prevents the discharge current from flowing through the anode support 44, so that the currents flow through the returns as designed.

### 2.3 Effects and Advantages

The chamber apparatus 10A according to the first embodiment is expected to reduce the uneven consumption of the discharge electrodes.

As a result, it is expected that the use of the chamber apparatus 10A according to the first embodiment improves the lasing performance.

Furthermore, as compared with a configuration in which the anode support 44 is replaced with the anode support 45 made of an insulating material and which is described with reference to FIG. 7, the chamber apparatus 10A according to the first embodiment, in which the size of the insulators 80 can be reduced, can be manufactured at low cost with a high yield, and can suppress damage due to the thermal expansion.

### 2.4 Variation of First Embodiment

The fixing structure shown in FIG. 9 has the configuration assembled in the following order: the anode support 44 and the insulators 80 are fixed to each other with the fixing bolts 86; and the insulators 80 together with the anode support 44 are then fixed with the fixing bolts 88, but may have another configuration. FIG. 10 shows an example of the other configuration. FIG. 10 shows another example of the cross-sectional view taken along the line 9-9 in FIG. 8.

The anode support 44 and the insulators 80 are fixed to each other with fixing bolts 87, and the insulators 80 and the upper case 60 are fixed to each other with fixing bolts 89, as shown in FIG. 10. The insulators 80 have through holes 91, through which the fixing bolts 87 pass, and through holes 93, through which the fixing bolts 89 pass. The through holes 91 and 93 may be counterbores that prevent the heads of the fixing bolts 87 and 89 from being exposed through the insulators 80. The upper case 60 has female threaded holes into which the fixing bolts 89 are screwed. The anode support 44 has female threaded holes into which the fixing bolts 87 are screwed, and through holes 94, through which the heads of the fixing bolts 89 pass.

### 3. Second Embodiment

### 3.1 Configuration

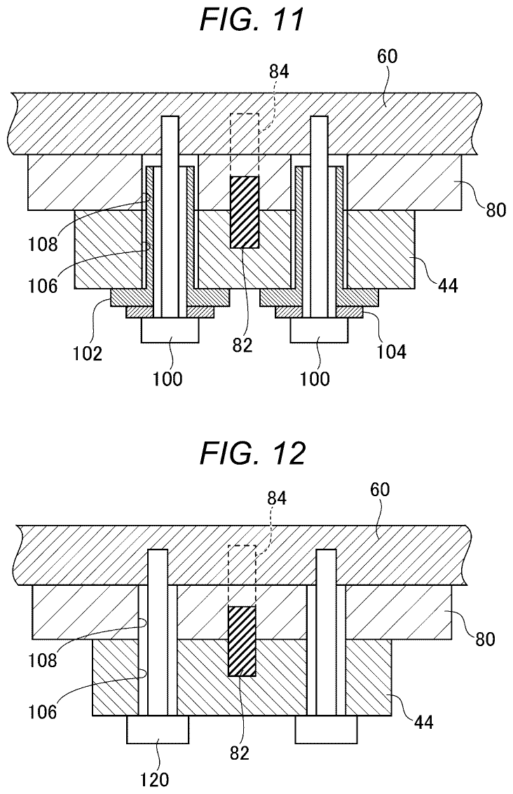

FIG. 11 shows a structure that fixes the anode support 44, the insulators 80, and the upper case 60 of the chamber apparatus 10A according to a second embodiment to each other. FIG. 11 shows another example of the cross-sectional view taken along the line 9-9 in FIG. 8. Differences in configuration between FIGS. 11 and 9 will be described.

In the chamber apparatus 10A according to the second embodiment shown in FIG. 11, the insulators 80 are disposed between the anode support 44 and the upper case 60, and the anode support 44 and the insulators 80 are fastened together and fixed to each other with fixing bolts 100. When the anode support 44 and the insulators 80 are fastened together, flanged sleeves 102 made of an insulating material are used to insulate the upper case 60 and the anode support 44 from each other. The fixing bolts 100 are desirably made of an insulating material such as a ceramic material, but may be made of metal.

The anode support 44 and the insulators 80 have through holes 106 and 108, respectively, which are used to fasten the two elements together, and the upper case 60 has female threaded holes into which the fixing bolts 100 are screwed. The flanged sleeves 102 are inserted into the through holes 106 and 108. The fixing bolts 100 are screwed into the female threaded holes of the upper case 60 via washers 104 and the flanged sleeves 102. The washers 104 may be made of metal, or may be insulating washers. The fixing bolts 100 are in contact with the anode support 44 via the flanged sleeves 102.

The other configurations of the chamber apparatus 10A according to the second embodiment are the same as those of the chamber apparatus 10A according to the first embodiment.

### 3.2 Operation

According to the configuration shown in FIG. 11, since the anode support 44 and the upper case 60 are insulated from each other by the insulators 80 and the flanged sleeves 102, the discharge current does not flow through the anode support 44. The currents thus flow through the returns as designed.

3.3 Effects and advantages

It is expected that the chamber apparatus 10A according to the second embodiment provides advantages that are the same as those provided by the chamber apparatus 10A according to the first embodiment.

In addition, the chamber apparatus 10A according to the second embodiment has a structure simpler than that of the chamber apparatus 10A according to the first embodiment, and has higher feasibility because only a few components need to be changed from those in the configuration of the chamber apparatus 10 according to Comparative Example and can be realized at low cost, and damage due to the thermal expansion is less probable.

### 4. Third Embodiment

### 4.1 Configuration

FIG. 12 shows a structure that fixes the anode support 44, the insulators 80, and the upper case 60 of the chamber apparatus 10A according to a third embodiment to each other. FIG. 12 shows another example of the cross-sectional view taken along the line 9-9 in FIG. 8. Differences in configuration between FIG. 12 and FIGS. 9 and 11 will be described.

In the chamber apparatus 10A according to the third embodiment shown in FIG. 12, the insulators 80 are disposed between the anode support 44 and the upper case 60, and the anode support 44 and the insulators 80 are fastened together and fixed to each other with fixing bolts 120. The fixing bolts 120 are desirably made of an insulating material such as a ceramic material, but may be made of metal.

The configuration in the third embodiment shown in FIG. 12 may be understood as the configuration in the second embodiment shown in FIG. 11 from which the flanged sleeves 102 and the washers 104 are excluded. The other configurations in the third embodiment are the same as those of the chamber apparatus 10A according to the second embodiment.

### 4.2 Operation

When the fixing bolts 120 are made of metal, the current paths between the anode support 44 and the upper case 60 at the end portions in the Z-axis direction are the fixing bolts 120 and therefore have high inductance. A current having an extreme magnitude is therefore restricted as compared with the case where the anode support 44 and the upper case 60 are in surface contact with each other. The currents thus flow through the returns as closely as designed.

4.3 Effects and advantages

It is expected that the chamber apparatus 10A according to the third embodiment provides advantages that are the same as those provided by the chamber apparatus 10A according to the second embodiment. The chamber apparatus 10A according to the third embodiment is a highly feasible embodiment, as the chamber apparatus 10A according to the second embodiment.

### 5. Fourth Embodiment

### 5.1 Configuration

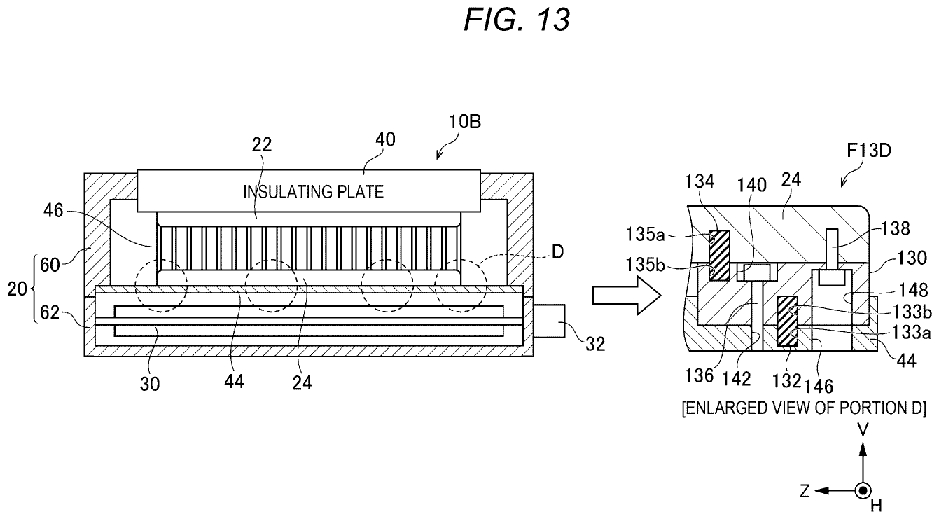

FIG. 13 shows the structure of a chamber apparatus 10B according to a fourth embodiment. A partially enlarged view F13D shown in the right part of FIG. 13 is an enlarged cross-sectional view of a portion of the chamber apparatus 10B that is the portion surrounded by a dashed circle D in FIG. 13, and shows a structure that fixes the anode support 44 to the anode 24. Differences in configuration between FIGS. 13 and 4 will be described.

In the chamber apparatus 10B according to the fourth embodiment, insulators 130 are disposed between the anode 24 and the anode support 44, and the anode 24 and the anode support 44 are insulated from each other by the insulators 130. The configuration described above uses multiple insulators 130 each shorter than the longitudinal length of the electrode length of the anode 24. In the example shown in FIG. 13, four insulators 130 are used. The positions surrounded by four dashed circles in FIG. 13 each represent the position where the insulator 130 is provided.

The number of the insulators 130 is not limited to four. The insulators 130 are desirably disposed at opposite ends of the anode 24 in the longitudinal direction. At least one of the multiple insulators 130 is desirably disposed between the opposite ends of the anode 24 in the longitudinal direction.

The longitudinal length of each of the insulators 130 can be designed as appropriate in accordance with the number of the insulators 130. The longitudinal length of the insulator 130 is desirably shorter than half of the longitudinal electrode length of the anode 24, and more desirably shorter than a quarter of the longitudinal electrode length of the anode 24.

Positioning pins 132 and 134 are disposed between the anode support 44 and each of the insulators 130 and between the anode 24 and each of the insulators 130, respectively, and the anode 24 is positioned with respect to the anode support 44 by the positioning pins 132 and 134.

The anode support 44 has holes 133a, into which the positioning pins 132 fit, and the insulators 130 each have holes 133b, into which the positioning pins 132 fit. The anode 24 has holes 135a, into which the positioning pins 134 fit, and the insulator 130 each have holes 135b, into which the positioning pins 134 fit.

One of the positioning pins 132 may be disposed at any one of the insulators 130. One of the positioning pins 134 may also be disposed at any one of the insulators 130. Out of the multiple insulators 130, an insulator at which the positioning pin 132 is disposed and an insulator at which the positioning pin 134 is disposed may be insulators disposed at different positions.

The anode support 44 and the insulators 130 are fixed to each other with fixing bolts 136, and the insulators 130 and the anode 24 are fixed to each other with fixing bolts 138, as shown in FIG. 13. The insulators 130 have through holes 140, through which the fixing bolts 136 pass, and through holes 148, through which the fixing bolts 138 pass. The through holes 140 and 148 may be counterbores that prevent the heads of the fixing bolts 136 and 138 from being exposed through the insulators 130.

The anode support 44 has female threaded holes 142, into which the fixing bolts 136 are screwed, and through holes 146, through which the heads of the fixing bolts 138 pass. The anode 24 has female threaded holes into which the fixing bolts 138 are screwed.

The insulators 130 are fixed to the anode support 44 and then fixed to the anode 24.

The other configurations of the chamber apparatus 10B according to the fourth embodiment are the same as those of the chamber apparatus 10 according to Comparative Example shown in FIG. 4.

### 5.2 Operation

The configuration in which the anode 24 and the anode support 44 are insulated from each other by the multiple insulators 130 prevents the discharge current from flowing through the anode support 44, so that the currents flow through the returns as designed.

5.3 Effects and advantages

It is expected that the chamber apparatus 10B according to the fourth embodiment provides advantages that are the same as those provided by the chamber apparatus 10A according to the first embodiment.

Furthermore, a method using the chamber apparatus 10B according to the fourth embodiment can be inexpensive, and can provide an improved yield and suppress damage due to the thermal expansion, as compared with a method using the anode support 45 entirely made of an insulating material.

### 6. Electronic Device Manufacturing Method

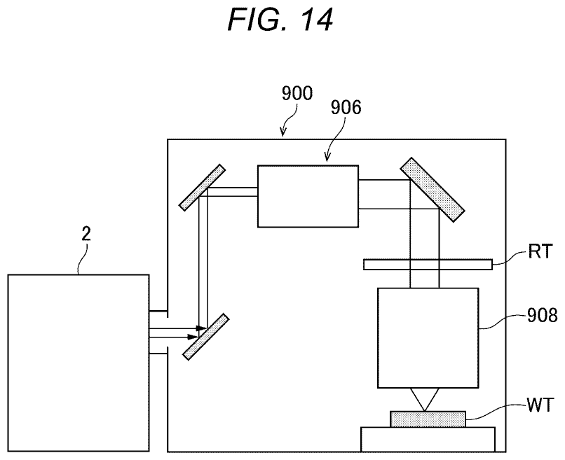

FIG. 14 schematically shows the configuration of the exposure apparatus 900. In FIG. 14, the exposure apparatus 900 includes an illumination optical system 906 and a projection optical system 908. The laser apparatus 2 includes the chamber apparatus 10A or 10B. The illumination optical system 906 illuminates a reticle pattern of a reticle that is not shown but is placed on a reticle stage RT with the laser light incident from the laser apparatus 2. The projection optical system 908 performs reduction projection on the laser light having passed through the reticle to bring the laser light into focus at a workpiece that is not shown but is placed on a workpiece table WT. The workpiece is a photosensitive substrate onto which a photoresist has been applied, such as a semiconductor wafer.

The exposure apparatus 900 translates the reticle stage RT and the workpiece table WT in synchronization with each other to expose the workpiece to the laser light having reflected the reticle pattern. Semiconductor devices can be manufactured by transferring the reticle pattern onto the semiconductor wafer in the exposure step described above and then carrying out multiple other steps. The semiconductor devices are an example of the “electronic devices” in the present disclosure.

### 7. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, the term “at least one of A, B, and C” should be interpreted to mean any of A, B, C, A+B, A+C, B+C, and A+B+C. Moreover, the term described above should be interpreted to include combinations of any thereof and any other than A, B, and C.

What is claimed is:

1. A laser chamber apparatus configured to output laser light, the laser chamber apparatus comprising:
a chamber body;
a first discharge electrode disposed in an internal space of the chamber body and having a longitudinal direction aligned with an optical axis of the laser light;
a second discharge electrode so disposed in the internal space that the second discharge electrode faces the first discharge electrode and has a longitudinal direction aligned with the optical axis of the laser light;
a return member electrically connecting the second discharge electrode to the chamber body over a length from one end to another end of the second discharge electrode in the longitudinal direction; and
a support member supporting the second discharge electrode with respect to the chamber body,
either of (i) the support member and the chamber body or (ii) the second discharge electrode and the support member being connected to each other via multiple insulators.

2. The laser chamber apparatus according to claim 1, wherein
the multiple insulators include a positioning mechanism defining a positional relationship between the support member and the chamber body or between the second discharge electrode and the support member.

3. The laser chamber apparatus according to claim 2, wherein
the positioning mechanism includes at least one of a positioning pin and a positioning hole.

4. The laser chamber apparatus according to claim 1, wherein
the multiple insulators are disposed between the support member and the chamber body at opposite ends of the support member in a longitudinal direction thereof.

5. The laser chamber apparatus according to claim 4, wherein
the multiple insulators are fixed to the support member and then fixed to the chamber body.

6. The laser chamber apparatus according to claim 4, wherein
the multiple insulators are each fixed to the chamber body with a bolt passing through the support member and the insulator.

7. The laser chamber apparatus according to claim 6, wherein the bolt is made of metal.

8. The laser chamber apparatus according to claim 6, wherein
the bolt is in contact with the support member via a flanged sleeve made of an insulating material.

9. The laser chamber apparatus according to claim 6, wherein
the bolt is made of an insulating material.

10. The laser chamber apparatus according to claim 1, wherein
at least one of the multiple insulators has a longitudinal length shorter than a longitudinal length of the second discharge electrode.

11. The laser chamber apparatus according to claim 10, wherein
at least one of the multiple insulators has a longitudinal length shorter than half of the longitudinal length of the second discharge electrode.

12. The laser chamber apparatus according to claim 10, wherein
at least one of the multiple insulators has a longitudinal length shorter than a quarter of the longitudinal length of the second discharge electrode.

13. The laser chamber apparatus according to claim 10, wherein
the multiple insulators are disposed between the second discharge electrode and the support member at opposite ends of the second discharge electrode in the longitudinal direction thereof.

14. The laser chamber apparatus according to claim 10, wherein
at least one of the multiple insulators is disposed between opposite ends of the second discharge electrode in the longitudinal direction thereof.

15. The laser chamber apparatus according to claim 10, wherein
the multiple insulators disposed between the second discharge electrode and the support member are fixed to the support member and then fixed to the second discharge electrode.

16. The laser chamber apparatus according to claim 1, wherein the support member is made of metal.

17. A laser apparatus comprising:
a laser chamber apparatus configured to output laser light,
the laser chamber apparatus including a chamber body,
a first discharge electrode disposed in an internal space of the chamber body and having a longitudinal direction aligned with an optical axis of the laser light,
a second discharge electrode so disposed in the internal space that the second discharge electrode faces the first discharge electrode and has a longitudinal direction aligned with the optical axis of the laser light,
a return member electrically connecting the second discharge electrode to the chamber body over a length from one end to another end of the second discharge electrode in the longitudinal direction, and
a support member supporting the second discharge electrode with respect to the chamber body,
either of (i) the support member and the chamber body or (ii) the second discharge electrode and the support member being connected to each other via multiple insulators.

18. An electronic device manufacturing method comprising:
generating laser light by using a laser apparatus;
outputting the laser light to an exposure apparatus; and
exposing a photosensitive substrate to the laser light in the exposure apparatus to manufacture electronic devices,
the laser apparatus including a laser chamber apparatus including a chamber body,
a first discharge electrode disposed in an internal space of the chamber body and having a longitudinal direction aligned with an optical axis of the laser light,
a second discharge electrode so disposed in the internal space that the second discharge electrode faces the first discharge electrode and has a longitudinal direction aligned with the optical axis of the laser light,
a return member electrically connecting the second discharge electrode to the chamber body over a length from one end to anther end of the second discharge electrode in the longitudinal direction, and
a support member supporting the second discharge electrode with respect to the chamber body,
either of (i) the support member and the chamber body or (ii) the second discharge electrode and the support member being connected to each other via multiple insulators.
